(19) United States
(12) Patent Application Publication
(10) Pub. No.: US 2008/0088301 A1
(43) Pub. Date: Apr. 17, 2008

(54) TESTING DEVICE HANDLER

(76) Inventors: Yie Wei Tan, Gelugor (MY); Pak Kee Choo, Bayan Lepas (MY); Chong Wei Chua, Prai (MY)

Correspondence Address: SCHWEGMAN, LUNDBERG & WOESSNER, P.A., P.O. BOX 2938, MINNEAPOLIS, MN, 55402, US

(21) Appl. No.: 11/536,971

(22) Filed: Sep. 29, 2006

(51) Int. Cl. G01R 31/28

(52) U.S. Cl. 324/158.1

(57) ABSTRACT

A semiconductor testing handler includes a chamber, at least one chuck attached within the chamber, and a plurality of heating elements disposed to place heat into the chamber. The semiconductor testing handler also includes an air handler disposed to move air through the chamber, and at least one temperature sensor positioned on the inside of the chamber. The semiconductor testing handler also has a control mechanism. A signal from the at least one temperature sensor is input to the control mechanism. The control mechanism controls the plurality of heating elements and the air handler to control the temperature of the chamber.

### BACKGROUND

The semiconductor industry has seen tremendous advances in technology in recent years that have permitted dramatic increases in circuit density and complexity. For example, present semiconductor technology now permits single-chip microprocessors with many millions of transistors, operating at speeds of tens (or even hundreds) of MIPS (millions of instructions per second), to be packaged in relatively small, air-cooled semiconductor device packages. Many purchasers of such semiconductor packages require 100% testing of the product before using it in another product. In addition, some industries find it advantageous to meet certain quality criteria such as ISO 9000, ISO 9001 and ISO 9002. Meeting these standards allows manufacturers to sell internationally. Quality standards include increased testing of products and attempts to achieve zero errors. As a result, manufacturers of semiconductor products are more inclined to test product than ever before in order to keep and win business.

Along with the increased emphasis on quality and testing in various industries, the semiconductor industry's dramatic increases in circuit density and complexity have given rise to semiconductors that use and dissipate more power. Testing of semiconductor devices or sets of semiconductor devices generally requires a test stand that holds a device under test. While the device is held in the test stand, electrical connections are made and tests are conducted to determine whether the semiconductor passes or fails certain tests. In addition, the capabilities of the semiconductor device may also be determined as part of grading the parts under test. While the semiconductor is in the test stand, it generates heat that must be dissipated. In some instances, a test stand may handle a plurality of chips or semiconductor devices under test. As a result, the heat produced by each of the chips or semiconductor devices must be removed from the test stand or test handler. Failure to remove the heat will stress the plurality of chips or semiconductor devices unnecessarily. If the heat cannot be removed by the testing apparatus, there is a possibility that the chipset will exceed a maximum juncture temperature specified. In addition, if the heat cannot be removed from the chips or the chip set associated with the device under test, a thermal runaway condition could also occur. This could damage the device under test.

In addition to being able to remove heat, the testing device must also have the ability to add heat to bring the device under test up to a testing temperature in a relatively short time. If the testing apparatus does not have the ability to bring the device under test up to temperature quickly, then testing throughput is affected. In other words, if the device under test is not brought up to temperature quickly this costs money as manufacturing and testing cannot be made as quickly. In one example embodiment, the maximum testing time is set for 25 seconds.

### BRIEF DESCRIPTION OF THE DRAWINGS

The invention is pointed out with particularity in the appended claims. However, a more complete understanding of the present invention may be derived by referring to the detailed description in connection with the figures, wherein like reference numbers refer to similar items throughout the figures and:

FIG. 1 illustrates a schematic diagram of a device handler and testing system, according to an example embodiment.

FIG. 2 is a side view of a temperature control unit, according to an example embodiment.

FIG. 3 is an interconnect diagram of a temperature control unit-device handler, according to an example embodiment.

FIG. 4 is a flow diagram of a method for controlling temperature in a device handling and testing system, according to an example embodiment.

FIG. 5 is a graph of time vs. temperature of a device handler and testing system that includes a temperature control unit for several devices (having power outputs from 25 watts to 45 watts), according to an example embodiment.

FIG. 6 illustrates a system, such as a computer system, according to an example embodiment.

FIG. 7 is a schematic diagram that shows a machine-readable medium, and an instruction set associated with the machine readable medium, according to an example embodiment.

The description set out herein illustrates the various embodiments of the invention and such description is not intended to be construed as limiting in any manner.

### DETAILED DESCRIPTION

In the following detailed description of the example embodiments, reference is made to the accompanying drawings that form a part hereof, and in which are shown by way of illustrating specific example embodiments. The example embodiments illustrated are described in sufficient detail to enable those skilled in the art to practice the teachings disclosed herein. Other example embodiments can be utilized and derived therefrom, such that structural and logical substitutions and changes can be made without departing from the scope of the claims. The following detailed description, therefore, is not to be taken in a limiting sense, and the scope of various embodiments is defined only by the appended claims, along with the full range of equivalents to which such claims are entitled.

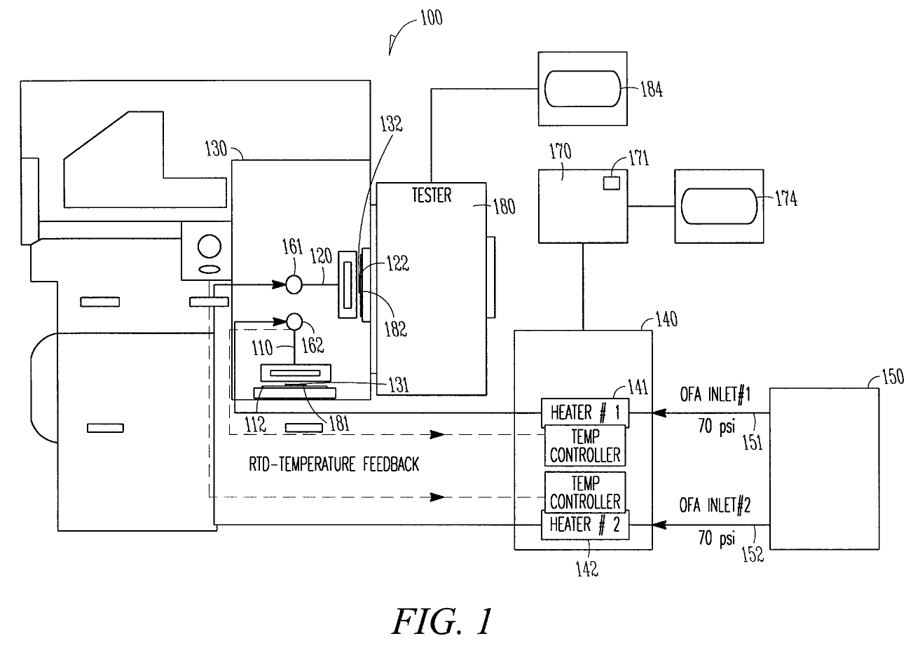

FIG. 1 illustrates a schematic diagram of a device handler and testing system 100, according to an example embodiment. The device handler and testing system 100 includes a chamber 130. The device handler and testing system 100 also includes a first chuck 110 within the chamber 130, and a second chuck 120 within the chamber 130. The first chuck 110 and the second chuck 120 are adapted to handle a device under test. As shown in FIG. 1, the first chuck 110 holds a device under test 112 and the second chuck 120 holds a device under test 122. The device handler and testing system 100 also includes a thermal control unit 140. The thermal control unit 140 includes a plurality of heating elements. As shown in FIG. 1, the thermal control unit 140 includes a first heating element 141 and a second heating element 142. The thermal control unit 140 also includes a first inlet 151 of substantially oil free air and a second inlet 152 of substantially oil free air. The first inlet 151 of substantially oil free air and the second inlet 152 of substantially oil free air deliver substantially oil free air from a source 150 of substantially oil free air. In another example embodiment, the first inlet 151 of substantially oil free air and the second inlet 152 of substantially oil free air deliver substantially oil free air from separate sources of substantially oil free air. The first heating element 141, and the second heating element 142 are disposed to place heat into the chamber 130. In one embodiment, the heated oil free air produced by the first heating element 141 and the second heating element 142 is placed near the devices under test 112, 122.

The device handler and testing system 100 also includes a first temperature sensor 161 positioned on the inside of the chamber 130, and a second temperature sensor 162 positioned on the inside of the chamber 130. The device handler and testing system 100 also includes a control mechanism 170 that receives inputs from the first temperature sensor 161 and the second temperature sensor 162. The control mechanism 170 controls the first heating element 141 and the second heating element 142 and the source of substantially oil free air 150 to control the temperature of the air which passes through or over the chucks 110, 120 within the chamber 130. The signals from the first temperature sensor 161 and the second temperature sensor 162 are fed back to the control mechanism 170. The control mechanism 170 uses these inputs as part of a feedback control mechanism. The inputs from the first temperature sensor 161 and the second temperature sensor 162 are used to adjust the heating elements 141 and 142 to heat or allow air from the source of substantially oil free air 150 to pass into the chamber over the chucks 110, 120 via inlets 151 and 152. The input from the temperature sensors 161 and 162 is used to determine an amount of heating at the first heating element 141 and at the second heating element 142.

The chucks 110, 120 hold the devices under test 112, 122, respectively. One purpose of the control mechanism 170 controlling heaters 141, 142 is to control or maintain the devices under test 112, 122 at a set temperature in the chamber 130. By controlling the temperature of the devices under test 112, 122 the devices under test 112, 122 are kept from overheating. Specifically, the device under test 112, 122 are kept at a temperature below the device junction temperature during testing. It should be noted that the heating or cooling required can be different for different devices under test 112, 122 within the chamber 130, and as a result, the heating elements 141 and 142 can act independently of one another to heat or cool the various devices under test within the chamber 130. In one embodiment, the first temperature sensor 161 is positioned near the first chuck 110 and the second temperature sensor 162 is positioned near the second chuck 120.

The device handler and testing system 100 also includes a testing apparatus 180 that is communicatively coupled to the chamber. The testing apparatus 180 includes a first set of contacts 181 associated with the first chuck 110 and a second set of contacts 182 associated with the second chuck 120. The first set of contacts 181 is adapted to contact a device under test positioned by the first chuck 110, and the second set of contacts 182 is adapted to contact a device under test positioned by the second chuck 120. The first chuck 110 moves the device under test into contact with the first set of contacts 181. The second chuck 120 moves the device under test into contact with the second set of contacts 182. In one example embodiment, the testing apparatus 180 also includes a display 184. The display 184 can be used to display test results or statistics related to test results, or can be used to display other types of information or data. For example, display 184 can show information on product such as pass fail binning, product health monitoring, and the like.

In one embodiment, the test site is at chuck 110. During testing, chuck 110 will engage to the test apparatus 180 through a TIU (test interface unit). After a device completes testing at chuck 120, the device handler rotates and swaps position between chuck 120 and chuck 110. The chuck 110 was preloaded with the device at location or contact set 181. Chuck 120 will place the tested device on the device carrier, and it will index to an output stacker, and chuck 120 will pick up another fresh (untested) device from another device carrier to continue the testing cycle.

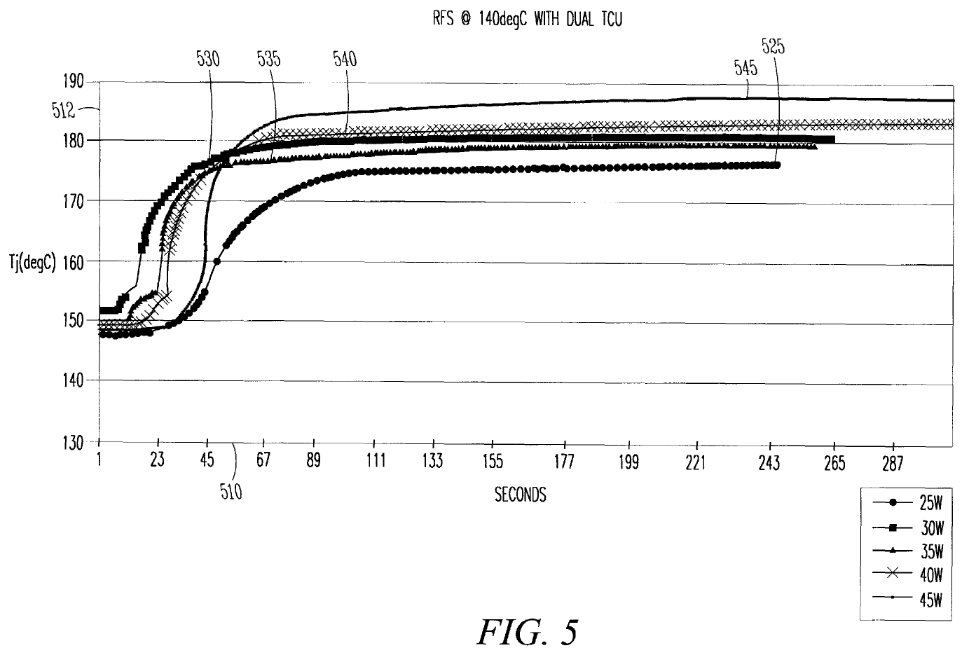

The control mechanism 170 of the device handler and testing system 100 acts in response to input from the first temperature sensor 161 and in response to input from the second temperature sensor 162 to control the temperature within a first zone 131 of the chamber 130 and a second zone 132 of the chamber 130. The control mechanism 170 may also be called a controller. The control mechanism 170 of the device handler and testing system 100 acts in response to input from the first temperature sensor 161 to heat air passing through the first heating element 141 to a level for controlling the temperature in a first zone 131. The control mechanism 170 also acts in response to input from the second temperature sensor 162 to heat air passing through the second heating element 142 to a level for controlling the temperature in a second zone 132. In one example embodiment, the control mechanism 170 includes a microprocessor 171. The microprocessor can be part of a stand-alone computing device or information handling system, such as a personal computer. In another example embodiment, the microprocessor 171 can be part of a printed circuit board. In another example embodiment, the thermal control unit 140 of the device handler and testing system 100 also includes a display 174 that displays information or data, such as an indication of the temperature at the first temperature sensor 161 and the temperature at the second temperature sensor 162. In another embodiment, the display 174 can also be used to display other information. The display 174 and the display 184 may be a single display in some example embodiments. One display might include a set of curves for a set of semiconductor devices, such as shown in FIG. 5, which will be discussed in more detail below.

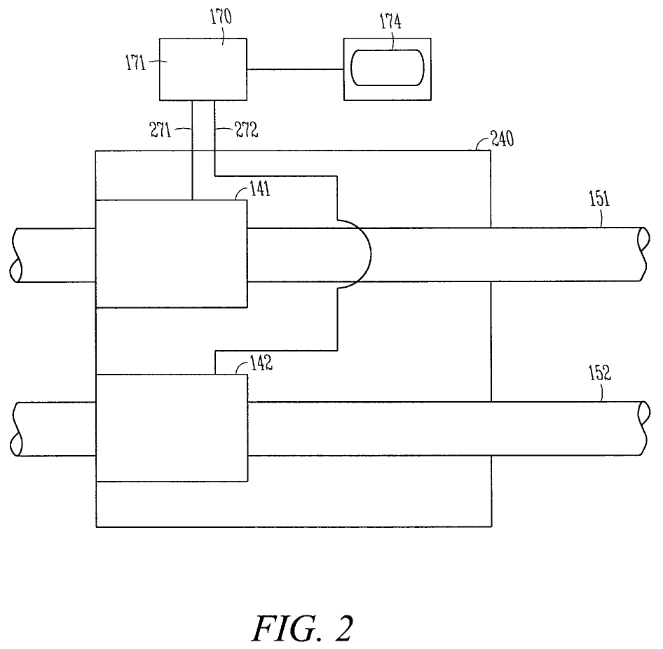

FIG. 2 is a side view of a thermal control unit 140, according to an example embodiment. Now referring to both FIG. 1 and FIG. 2, the thermal control unit 140 will be further discussed. The thermal control unit 140 includes a housing 240. Substantially oil free air is input through inlets 151 and 152. The substantially oil free air passing through the first inlet 151 is passed through the first heating element 141. In some instances, such as when heat needs to be added to a zone 131 associated with the first chuck 110, the air is heated using the first heating element 141 and passed to the area or zone near the first chuck 110. In other instances, the zone 131 near the first chuck needs to be cooled. In this instance the air passing through the first heating element 141 is not heated and passed directly to the first chuck 110. The microprocessor 171, such as a computer, monitors the temperature at the first chuck 110 using the first temperature sensor 161. The temperature at the first temperature sensor 161 is an indication of whether the zone 131 needs to be heated or cooled. If the temperature is less than a desired amount, the microprocessor enables the first heating element 141 by passing an enabling signal over a control line 271. If the temperature is greater than a desired amount, the microprocessor disables the first heating element 141 by passing a disabling signal over the control line 271. This allows unheated air to pass into the zone 131 of the chamber 130. The unheated air in the zone 131 picks up heat and is removed from the chamber 130, thereby cooling the chamber 130 or, more specifically, the zone 131 of the chamber 130.

The second inlet 152 also moves air through the second heating element 142. The air is heated or cooled in a similar way to the inlet 151 and the first heating element 141. The heated or cooled air is delivered to the second zone 132 at or near the second chuck 120. The microprocessor 171, such as a computer, monitors the temperature at the second chuck 120 using the second temperature sensor 162. The temperature at the second temperature sensor 162 is an indication of whether the zone 132 needs to be heated or cooled. If the temperature is less than a desired amount, the microprocessor enables the second heating element 142 by passing an enabling signal over a control line 272. If the temperature is greater than a desired amount, the microprocessor disables the second heating element 142 by passing a disabling signal over the control line 272. This allows unheated air to pass into the zone 132 of the chamber 130. The unheated air in the zone 132 picks up heat and is removed from the chamber 130, thereby cooling the chamber 130 or, more specifically, the zone 132 of the chamber 130.

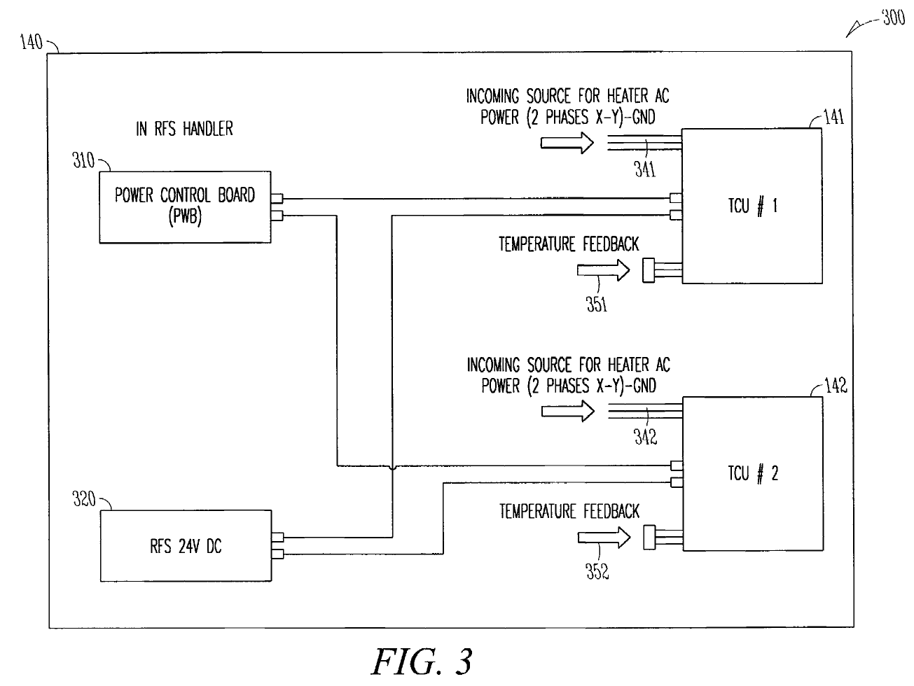

FIG. 3 is an interconnect diagram 300 of a thermal control unit 140, according to an example embodiment. The interconnect diagram 300 shows the connection between the first heating element 141, the second heating element 142, a power control board 310 and a power source 320. The power source 320 is a source of direct current power that provides power for controlling the temperature controller within the thermal control unit 140. The thermal control unit 140 also includes an alternating current power source of two-phase power, which is depicted by an input 341 of two-phase alternating current, and an input 342 of two-phase alternating current. As shown in FIG. 3, each of the inputs 341 and 342 also includes a ground connection. The first heating element 141 also includes a first temperature feedback 351 from the first chuck. The second heating element 142 also includes a second temperature feedback 352 from the second chuck. In some embodiments, the first temperature feedback 351 and the second temperature feedback 352 are from areas or volumes near the first and second chucks, respectively, or from the first zone 131 and the second zone 132 (See. FIG. 1) within the chamber 130 of the device handler and testing system 100 (see FIG. 1). The power control board 310 controls the power delivered to the first heating element 141 and the second heating element 142. For example, the power control board 310 shuts off power in response to a need to cool a first or second zone 131, 132 (See. FIG. 1) or chuck within the chamber 130 (see FIG. 1). The power control board 310 also enables power to the first heating element 141 or the second heating element 142 in response to a need to heat the first zone or second zone 131, 132 (See. FIG. 1) or first chuck or second chuck within the chamber (see FIG. 1), respectively. The power control board 310 also disables power to the device handler and testing system 100 including the thermal control unit 140 when an interrupt command is received, such as from a machine interlock condition or a emergency power off condition. The power control board 310 is connected to the power source 320 for safety control purposes. For example, when the device handler is shut down, power to the power source 320 will cut off as well.

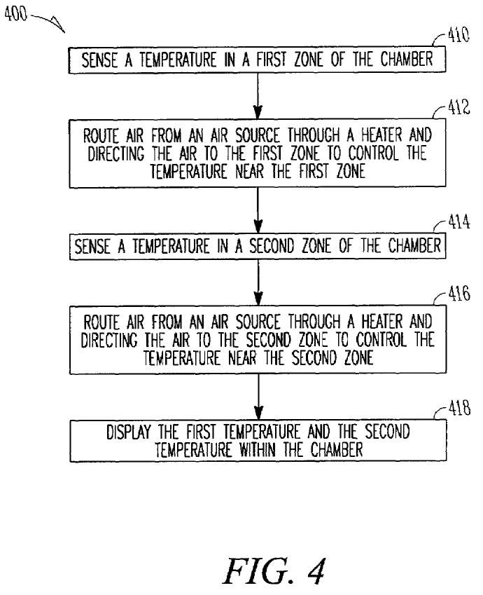

FIG. 4 is a flow diagram of a method 400 for controlling temperature in a device handling and testing system, according to an example embodiment. The method 400 of controlling temperature within a test chamber having a plurality of chucks for handling a plurality of devices under test includes sensing a temperature in a first zone of the chamber 410, routing air from an air source through a heater and directing the air to the first zone to control the temperature near the first zone 412, sensing a temperature in a second zone of the chamber 414, and routing air from an air source through a heater and directing the air to the second zone to control the temperature near the second zone 416. The temperature sensor of the first zone is placed proximate to a first chuck for holding a first device in a chamber and the temperature sensor of the second zone is placed proximate to a second chuck for holding a first device in a chamber. In one embodiment, routing air through a heater 412, 416 includes passing the air through the heating element without heating the air and directing the air to either the first zone or the second zone, respectively. Passing unheated air through the heating elements occurs when either the first zone or the second zone needs to be cooled. In another embodiment, the method 400 of controlling temperature within a test chamber also includes displaying the first temperature and the second temperature within the chamber 418.

In one embodiment, the method includes setting the desired temperature per product (device under test) requirement through both temperature controllers 141, 142, 341, 342. The control mechanism 170 temperature controllers will power the associated heaters 341, 342 to heat the oil free air passing through the heater. The temperature sensors 161, 162 will read back the actual temperature at chucks 110, 120. Then temperature controller 170 will determine the amount of power to deliver to each heater 141, 142, 341, 342 until the set temperature within ±2° C. is reached. The read back (actual vs. set temperature) will display on a user interface such as display 174.

FIG. 5 is a graph of time vs. temperature of a device handler and testing system that includes a temperature control unit for several devices (having power outputs from 25 watts to 45 watts), according to an example embodiment. The x-axis 510 of the graph denotes time in seconds. The y-axis 512 of the graph denotes the temperature of the device in degrees centigrade (“C”). The graph shows heating and cooling curves for a device 525, a device 530, a device 535, a device 540 and a device 545. The device 525 has a power output of approximately 25 watts, the device 530 has a power output of approximately 30 watts, the device 535 has a power output of approximately 35 watts, the device 540 has a power output of approximately 40 watts, and the device 545 has a power output of approximately 45 watts. The graph shown in FIG. 5 is the temperature rise over time which is the simulation on heat generation during testing (transistors toggling) with constant power (worst case) to the device under test. As shown by the graph, the temperature will initially ramp steeply, followed by a gradual climb and then stabilize at constant temperature over time. This graph will be used to determine the correct set temperature for a device under test having a defined test time and product junction temperature rise.

The graph also shows that each of the devices 525, 530, 535, 540 and 545 can be placed in the chamber 130 (see FIG. 1) of the device handler and testing system 100, which is initially at approximately 150 degrees C. The device, such as devices 525, 530, 535, 540 and 545, can be powered up within the chamber 130 (see FIG. 1) and within approximately 30-45 seconds, the temperature within the zone or portion of the chamber is raised anywhere from 20-30 degrees C., and is maintained for the remaining time by the thermal control unit 140. In other words, after approximately 30-45 seconds, the temperature within the chamber 130 or portion of the chamber 130 is under control and saturated. The temperature is the operating temperature or desired temperature at which the testing is conducted. With other systems, the temperature can continue to ramp up and the result is a thermal runaway and damage to the device, such as devices 525, 530, 535, 540 and 545.

A semiconductor testing handler includes a chamber, at least one chuck attached within the chamber, and a plurality of heating elements disposed to place heat into the chamber. The semiconductor testing handler also includes an air handler disposed to move air through the chamber, and at least one temperature sensor positioned on the inside of the chamber. The semiconductor testing handler also has a control mechanism. A signal from the at least one temperature sensor input to the control mechanism. The control mechanism controls the plurality of heating elements and the air handler to control the temperature of the chamber. The semiconductor testing handler also includes a testing apparatus communicatively coupled to the at least one chuck. The testing apparatus is adapted to test a semiconductor device under test. In one embodiment, the control mechanism adds heat to the chamber with the plurality of heating elements to bring the chamber to a testing temperature and removes heat from the chamber to maintain the testing chamber within a range of test temperatures. In another example embodiment of the semiconductor testing handler, the air handler is disposed to move substantially oil free air through the chamber. The semiconductor testing handler includes a source of substantially oil free air. The testing apparatus of the semiconductor testing handler includes electrical contacts, and testing electronics communicatively coupled to the electrical contacts. The at least one chuck attached within the chamber is adapted to move a device under test into contact with the electrical contacts. The semiconductor testing handler also includes a source of substantially oil free air. The air handler is disposed to move substantially oil free air through the chamber. The source of substantially oil free air is input to at least one of the plurality of heating elements. In one embodiment, the semiconductor testing handler moves substantially oil free air to a plurality of the heating elements. In another example embodiment, the semiconductor testing handler further includes a processor, and an instruction set executable on the processor. The instruction set causes the processor and testing electronics to produce a plurality of signals at the electrical contacts for testing a device under test. The instruction set can also cause controlled responses from the air handler and the plurality of heating elements to heat or cool the chamber.

As mentioned above, the device handler and testing system 100 includes a microprocessor 171 (see FIG. 1) which can be part of a computer system. In addition, the testing apparatus 180 (see FIG. 1) can also be part of a computer system. It should be noted that the testing apparatus 180 and the microprocessor 171 associated with the thermal control unit 140 can be separate computing systems or, in the alternative, separate parts of a computing system.

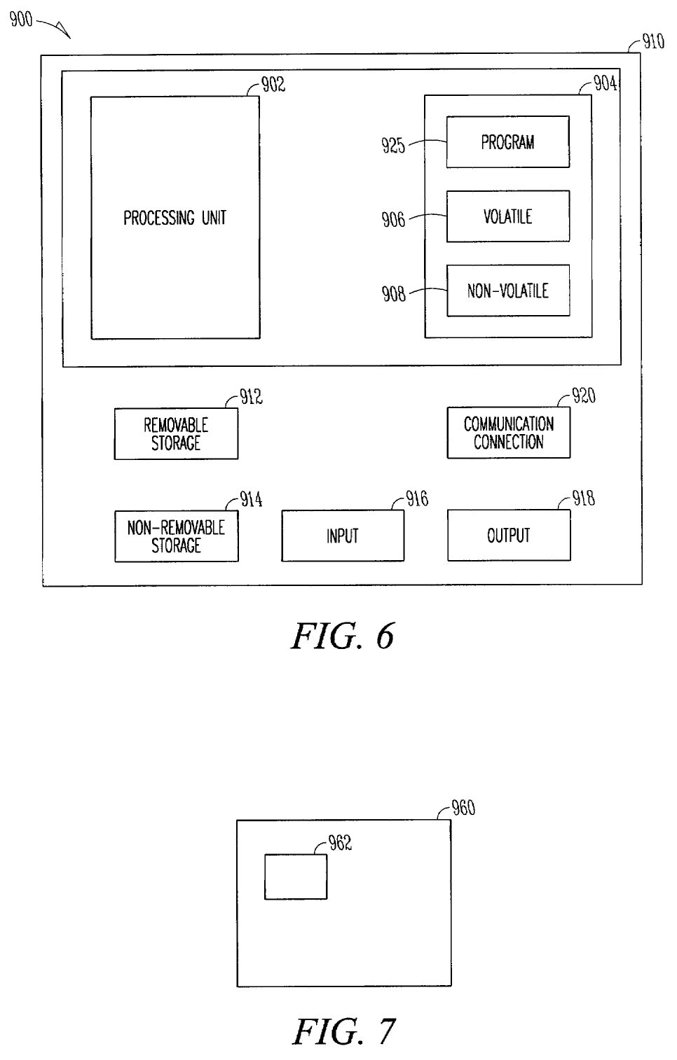

FIG. 6 illustrates a system, such as a computer system 900, according to an example embodiment. A block diagram of a computer system that executes programming for performing the above algorithm as shown in FIG. 4. A general computing device in the form of a computer 910, may include a processing unit 902, memory 904, removable storage 912, and non-removable storage 914. Memory 904 may include volatile memory 906 and non-volatile memory 908. Computer 910 may include any type of information handling system in any type of computing environment that includes any type of computer-readable media, such as volatile memory 906 and non-volatile memory 908, removable storage 912 and non-removable storage 914. Computer storage includes random access memory (RAM), read only memory (ROM), erasable programmable read-only memory (EPROM) and electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage or other magnetic storage devices, or any other medium capable of storing computer-readable instructions. Computer 910 may include or have access to a computing environment that includes input 916, output 918, and a communication connection 920. The computer may operate in a networked environment using a communication connection to connect to one or more remote computers. The remote computer may include a personal computer (PC), server, router, network PC, a peer device or other common network node, or the like. The communication connection may include a Local Area Network (LAN), a Wide Area Network (WAN) or other networks. A microprocessor or controller associated with the device handler and testing system 100 (see FIG. 1) is also such a computer system.

Computer-readable instructions stored on a machine-readable medium are executable by the processing unit 902 of the computer 910. A hard drive, CD-ROM, and RAM are some examples of articles including a machine-readable medium. For example, a computer program 925 may be executed to control the heating and cooling of the chamber 130 (see FIG. 1) according to the above teachings. The instructions may be included on a CD-ROM and loaded from the CD-ROM onto a hard drive. The computer program may also be termed firmware associated with the device handler and testing system 100. In some embodiments, a copy of the computer program 925 can also be stored on the disk 120 of a disk drive.

In should be noted that a computer is not required in some embodiments. In some embodiments a temperature controller, sensor feedback and a simple user interface display on thermal control unit can be used in place of a computer.

FIG. 7 is a schematic diagram that shows a machine-readable medium 960 and an instruction set 962 associated with the machine readable medium 960, according to an example embodiment. The machine-readable medium 960 provides instructions 962 that, when executed by a machine, such as a computer, cause the machine to perform the operations discussed above in FIGS. 1-5.

Although various embodiments have been described with reference to specific example embodiments, it will be evident that various modifications and changes may be made to these embodiments without departing from the broader spirit and scope of the disclosed subject matter. Accordingly, the specification and drawings are to be regarded in an illustrative rather than a restrictive sense.

The foregoing description of the specific embodiments reveals the general nature of the technology sufficiently that others can, by applying current knowledge, readily modify and/or adapt it for various applications without departing from the generic concept, and therefore such adaptations and modifications are intended to be comprehended within the meaning and range of equivalents of the disclosed embodiments. It is to be understood that the phraseology or terminology employed herein is for the purpose of description and not of limitation. Accordingly, the invention is intended to embrace all such alternatives, modifications, equivalents and variations as fall within the spirit and broad scope of the appended claims.

What is claimed is:

1. A semiconductor testing handler comprising:
a chamber;
at least one chuck attached within the chamber;
a plurality of heating elements disposed to place heat into the chamber;
an air handler disposed to move air through the chamber;
at least one temperature sensor positioned on the inside of the chamber;
a control mechanism, a signal from the at least one temperature sensor input to the control mechanism, the control mechanism controlling the plurality of heating elements, and the air handler to control the temperature of the chamber; and
a testing apparatus communicatively coupled to the at least one chuck, the testing apparatus adapted to test a semiconductor device under test.

2. The semiconductor testing handler of claim 1, wherein the control mechanism adds heat to the chamber with the plurality of heating elements to bring the chamber to a testing temperature and removes heat from the chamber to maintain the testing chamber within a range of test temperatures.

3. The semiconductor testing handler of claim 1, wherein the air handler is disposed to move substantially oil free air through the chamber.

4. The semiconductor testing handler of claim 1, further comprising a source of substantially oil free air, the air handler is disposed to move substantially oil free air through the chamber.

5. The semiconductor testing handler of claim 1, wherein the testing apparatus further includes:
electrical contacts; and
testing electronics communicatively coupled to the electrical contacts.

6. The semiconductor testing handler of claim 5, wherein the at least one chuck attached within the chamber is adapted to move a device under test into contact with the electrical contacts.

7. The semiconductor testing handler of claim 1, further comprising a source of substantially oil free air, the air handler disposed moves substantially oil free air through the chamber, the source of substantially oil free air input to at least one of the plurality of heating elements.

8. The semiconductor testing handler of claim 1, further comprising a source of substantially oil free air, the air handler disposed moves substantially oil free air through the chamber, the source of substantially oil free air input to a plurality of the heating elements.

9. The semiconductor testing handler of claim 5, wherein the testing apparatus further includes:
a processor; and
an instruction set executable on the processor, the instruction set causing the processor and testing electronics to produce a plurality of signals at the electrical contacts for testing a device under test.

10. A device handler and testing system comprising:
a chamber;
a first chuck within the chamber;
a second chuck within the chamber, the first chuck and the second chuck adapted to handle a device under test;
a first heating element disposed to place heat into the chamber;
a second heating element disposed to place heat into the chamber;
a source of substantially oil free air;
a first temperature sensor positioned on the inside of the chamber;
a second temperature sensor positioned on the inside of the chamber;
a control mechanism that receives inputs from the first temperature sensor and the second temperature sensor, the control mechanism controlling the first heating element and the second heating element and the source of substantially oil free air to control the temperature within the chamber; and
a testing apparatus communicatively coupled to the chamber, the testing apparatus including a first set of contacts associated with the first chuck and a second set of contacts associated with the second chuck, the first set of contacts adapted to contact a device under test positioned by the first check and the second set of contacts adapted to contact a device under test positioned by the second chuck.

11. The device handler and testing system of claim 10, wherein the first temperature sensor is positioned near the first chuck.

12. The device handler and testing system of claim 11, wherein the second temperature sensor is positioned near the second chuck.

13. The device handler and testing system of claim 10, further comprising an air handler, wherein the air handler inputs air from the source of substantially oil free air to a first heater and a second heater.

14. The device handler and testing system of claim 10, wherein the controller acts in response to input from the first temperature sensor and in response to input from the second temperature sensor to control the temperature within a first zone of the chamber and a second zone of the chamber.

15. The device handler and testing system of claim 10, further comprising an air handler, wherein the controller acts in response to input from the first temperature sensor to heat air passing through the first heating element to a level for controlling the temperature in a first zone, and wherein the controller acts in response to input from the second temperature sensor to heat air passing through the second heating element to a level for controlling the temperature in a second zone.

16. The device handler and testing system of claim 15, wherein the controller includes a microprocessor.

17. The device handler and testing system of claim 15, further including a display that indicates the temperature at the first sensor and the temperature at the second sensor.

18. A method of controlling temperature within a test chamber having a plurality of chucks for handling a plurality of devices under test, the method comprising:
sensing a temperature in a first zone of the chamber;
routing air from an air source through a heater and directing the air to the first zone to control the temperature near the first zone;
sensing a temperature in a second zone of the chamber; and
routing air from an air source through a heater and directing the air to the second zone to control the temperature near the second zone.

19. The method of controlling temperature within a test chamber of claim 18, wherein the temperature sensor of the first zone is placed proximate a first chuck for holding a first device in a chamber.

20. The method of controlling temperature within a test chamber of claim 19, wherein the temperature sensor of the second zone is placed proximate a second chuck for holding a first device in a chamber.

21. The method of controlling temperature within a test chamber of claim 18, wherein air is passed through the heating element without heating the air and directed to either the first zone or the second zone when either the first zone or the second zone needs to be cooled.

22. The method of controlling temperature within a test chamber of claim 18, further comprising displaying the first temperature and the second temperature within the chamber.
